(19) United States
(12) Patent Application Publication
(10) Pub. No.: US 2024/0038641 A1
(43) Pub. Date: Feb. 1, 2024

(54) Elastomer Interconnection Substrate Layer

(71) Applicant: Avago Technologies International Sales Pte. Limited, Singapore (SG)

(72) Inventors: Dharmendra Saraswat, Foothill Ranch, CA (US); Sam Karikalan, Ladera Ranch, CA (US); Sam Zhao, Irvine, CA (US); Mayank Mayukh, Fort Collins, CO (US); Arun Ramakrishnan, Lake Forest, CA (US); Reza Sharifi, Irvine, CA (US); Liming Tsau, Irvine, CA (US)

(21) Appl. No.: 17/876,189

(22) Filed: Jul. 28, 2022

(51) Int. Cl. H01L 23/498; H01L 21/48

(52) U.S. Cl. CPC H01L 23/49811; H01L 23/49816; H01L 23/49833; H01L 23/49838; H01L 21/4853

(57) ABSTRACT

Novel tools and techniques are provided for implementing a substrate with an elastomer layer. The substrate might include one or more interconnects and an elastomer layer comprising at least one conductor. In some instances, the at least one conductor of the elastomer layer couples to at least one of the one or more interconnects of the substrate. Additionally, the at least one conductor is configured to couple at least one of the one or more interconnects of the substrate to a circuit board.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods, systems, and apparatuses for providing a substrate with an elastomer layer to couple one or more interconnects of the substrate to a circuit board.

### BACKGROUND

Conventionally, solder balls are used to couple one or more interconnects of a substrate to a circuit board. However, solder balls can often cause impedance discontinuity at the substrate to circuit board interface. Additionally, the manufacturing and assembly process of a semiconductor package often results in solder balls with an unpredictable shape and size. This can cause unexpected problems in a semiconductor package's signal integrity performance resulting in insertion loss and return loss. Further, the one or more solder balls might be fragile and easy to break off at the substrate to circuit board interface.

In order to address one or more issues associated with conventional solder balls, methods, systems, and apparatuses are provided for implementing a substrate with an elastomer layer to interconnect and couple one or more interconnects of the substrate to a circuit board.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIGS. 1A-1F (collectively, FIG. 1) are schematic cross-sectional views of a semiconductor device with an elastomer substrate layer, in accordance with various embodiments;

FIGS. 2A-2E (collectively, FIG. 2) are schematic cross-sectional views of substrate arrangements with an elastomer layer for a semiconductor module, in accordance with various embodiments;

FIG. 3 is a schematic cross-sectional view of a substrate arrangement with a bottom view of one or more interconnects to connect an elastomer layer to a substrate, in accordance with various embodiments; and

FIG. 4 is a flow diagram of a method of manufacturing a substrate with an elastomer layer, in accordance with various embodiments.

### DETAILED DESCRIPTION OF EMBODIMENTS

Various embodiments set forth a substrate with an elastomer layer, and methods of manufacturing a substrate with an elastomer layer.

In an aspect, a substrate with an elastomer layer is provided. The substrate might include one or more interconnects and an elastomer layer. The elastomer layer might include at least one conductor. The at least one conductor is aligned with and/or coupled to at least one of the one or more interconnects of the substrate and the at least one conductor is configured to couple the at least one of the one or more interconnects of the substrate to a circuit board.

In some embodiments, the one or more interconnects at least partially extend into the elastomer layer to form or to couple to the at least one conductor of the elastomer layer.

Additionally, in various cases, the elastomer layer further comprises a non-conductive elastomer body. In some cases, the at least one conductor of the elastomer layer is contained within the non-conductive elastomer body. In other cases, the at least one conductor of the elastomer layer surrounds an outer surface of the non-conductive elastomer body. Alternatively, the elastomer layer itself may be the conductor.

In some embodiments, the elastomer layer may be a pin, a post, or a bump. The at least one conductor at least partially surrounds an outer surface of a non-conductive body of the at least one pin, post, or bump.

In another aspect, a semiconductor package with a substrate with an elastomer layer is provided. The semiconductor package might include a first die and a substrate coupled to the first die. The substrate might include one or more interconnects and an elastomer layer. The elastomer layer might include at least one conductor. The at least one conductor is aligned with and/or coupled to at least one of the one or more interconnects of the substrate and the at least one conductor is configured to couple the at least one of the one or more interconnects of the substrate to a circuit board.

In some embodiments, the one or more interconnects at least partially extend into the elastomer layer to form or to couple to the at least one conductor of the elastomer layer.

Additionally, in various cases, the elastomer layer further comprises a non-conductive elastomer body. The at least one conductor of the elastomer layer is contained within the non-conductive elastomer body. In other cases, the at least one conductor of the elastomer layer surrounds an outer surface of the non-conductive elastomer body. Alternatively, the elastomer layer itself may be the conductor.

In some embodiments, the elastomer layer may be a pin, a post, or a bump. The at least one conductor at least partially surrounds an outer surface of a non-conductive body of the at least one pin, post, or bump.

In yet another aspect, a method of manufacturing a substrate with an elastomer layer is provided. The method includes forming a substrate comprising (i) one or more interconnects and (ii) an elastomer layer. The elastomer layer includes at least one conductor. In some instances, forming the elastomer layer further includes coupling at least one of the one or more interconnects of the substrate to a circuit board via the at least one conductor

In some cases, the one or more interconnects or the circuit board comprises one or more ring pad connections or one or more solid pad connections. In various instances, the one or more interconnects at least partially extend into the elastomer layer to form or to couple to the at least one conductor of the elastomer layer and the elastomer layer is formed on the one or more interconnects to surround the one or more interconnects at least partially extending into the elastomer layer.

In various embodiments, the elastomer layer further comprises a non-conductive elastomer body and the at least one conductor of the elastomer layer is contained within the non-conductive elastomer body. The at least one conductor of the elastomer layer may at least partially extend from the non-conductive elastomer body to couple to the circuit board. Alternatively, the elastomer layer itself may be conductive and form the at least one conductor.

The method might additionally include forming the elastomer layer as at least one pin, post, or bump comprising the at least one conductor and coupling the at least one conductor to at least one of the one or more interconnects of the substrate. In some case, the at least one pin, post, or bump comprises a non-conductive elastomer body. The at least one conductor of the at least one pin, post, or bump is contained within the non-conductive elastomer body. In other cases, the at least one conductor at least partially surrounds or coats an outer surface of the non-conductive elastomer body. Alternatively, the at least one pin, post, or bump itself may be the conductor.

In some cases, the method might include coating at least part of an outer surface of the elastomer body with the at least one conductor.

The method might also include coating the at least one of the one or more interconnects with a conductive material and coating at least part of an outer surface of the elastomer body with the at least one conductor. Next, the method might continue by forming the elastomer layer on the one or more interconnects by coupling the at least one conductor of the elastomer layer on the at least one of the one or more interconnects coated with the conductive material.

In various instances, the method might include forming the elastomer layer on a surface of one or more first layers of the substrate as a body extending along an axis parallel to a plane defined by the surface of the one or more first layers of the substrate.

In the following description, for the purposes of explanation, numerous details are set forth to provide a thorough understanding of the described embodiments. It will be apparent to one skilled in the art, however, that other embodiments may be practiced without some of these details. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Similarly, when an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

Likewise, when an element is referred to herein as being a “layer,” it is to be understood that the layer can be a single layer or include multiple layers. When a layer is described as being coupled or connected to another layer, it is to be understood that the coupled or connected layers may include intervening elements present between the coupled or connected layers. In contrast, when a layer is referred to as being “directly” connected or coupled to another layer, it should be understood that no intervening elements are present between the layers. However, the existence of directly coupled or connected layers does not exclude other connections in which intervening layers may be present.

Additionally, it should be understood that spatial or order descriptions (e.g., “above,” “below,” “up,” “left,” “right,” “down,” “top,” “bottom,” “middle,” “vertical,” “horizontal,” “first,” “second,” etc.) used herein are for purposes of illustration only, and that practical implementations of the structures described herein can be spatially arranged in any orientation, order, or manner.

Furthermore, the methods and processes described herein may be described in a particular order for ease of description. However, it should be understood that, unless the context dictates otherwise, intervening processes may take place before and/or after any portion of the described process, and further various procedures may be reordered, added, and/or omitted in accordance with various embodiments.

Unless otherwise indicated, all numbers used herein to express quantities, dimensions, and so forth should be understood as being modified in all instances by the term “about.” In this application, the use of the singular includes the plural unless specifically stated otherwise, and use of the terms “and” and “or” means “and/or” unless otherwise indicated. Additionally, use of the phrase “at least one of ‘A’ and ‘B’” or “at least one of ‘A’ or ‘B” means “at least one of ‘A’ and/or at least one of ‘B’” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

In conventional semiconductor or chip packages, one or more solder balls may be used to couple one or more interconnects of a substrate to a circuit board. The one or more solder balls may often have unpredictable shapes and sizes resulting in impedance discontinuity at the substrate to circuit board interface. Additionally, the one or more solder balls might be fragile and easy to break off at the substrate to circuit board interface.

The proposed substrate provides an elastomer layer as a last layer at the substrate to circuit board interface. The elastomer layer may have one or more conductors that have a predictable shape and size. By having conductors with a predictable shape and size, the impedance at the substrate to circuit board interface may be easily predicted. Additionally, by having an elastomer layer, the conductors between the substrate and the circuit board are less likely to break or crack. Additionally, by implementing an elastomer layer of the substrate, package warpage may be reduced.

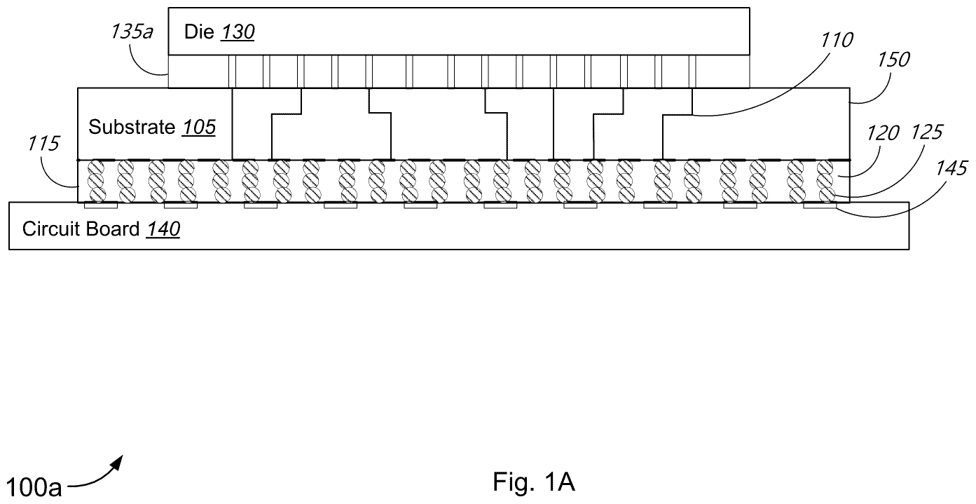

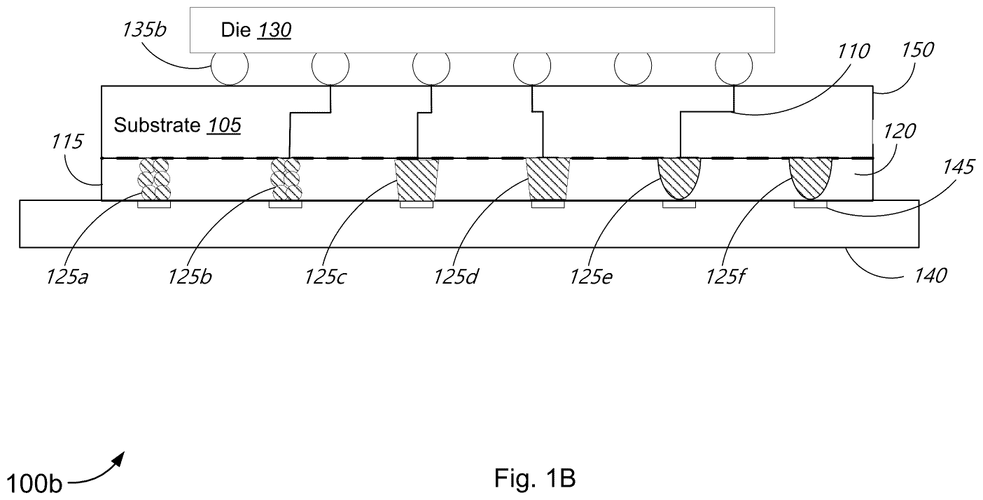

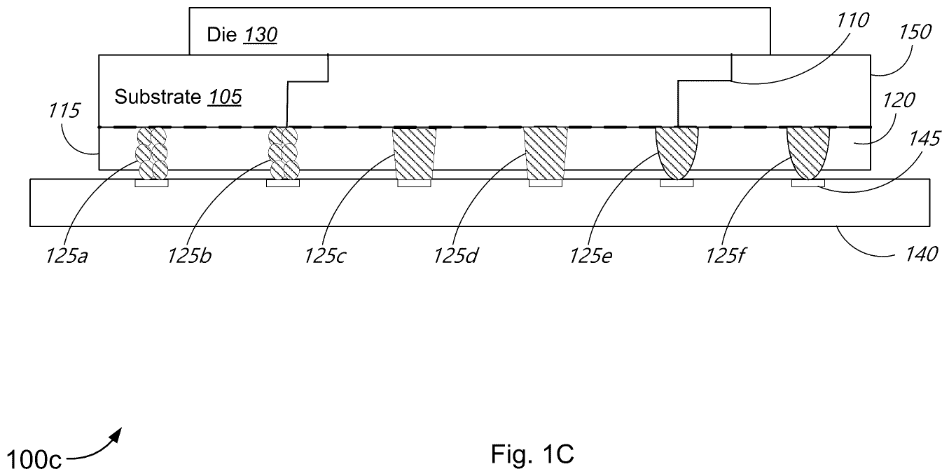

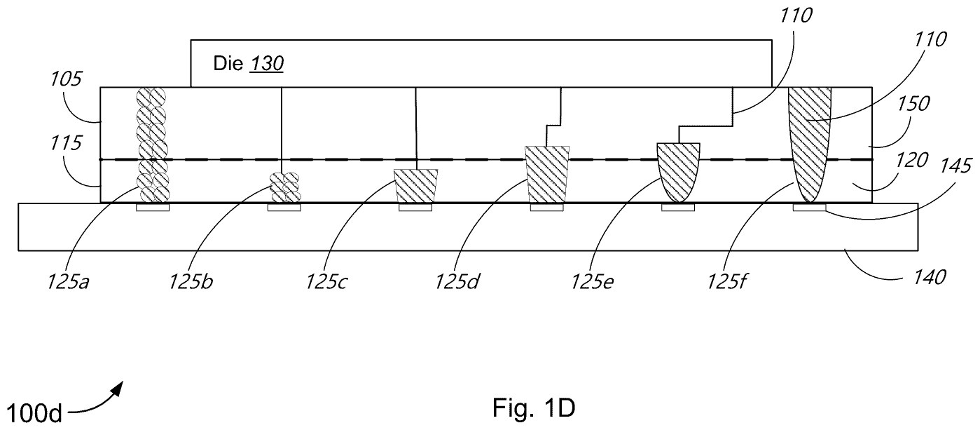

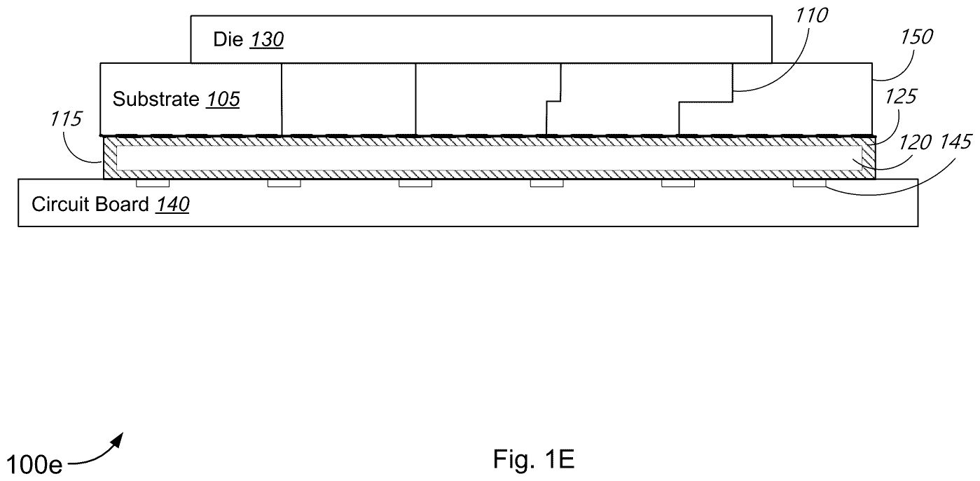

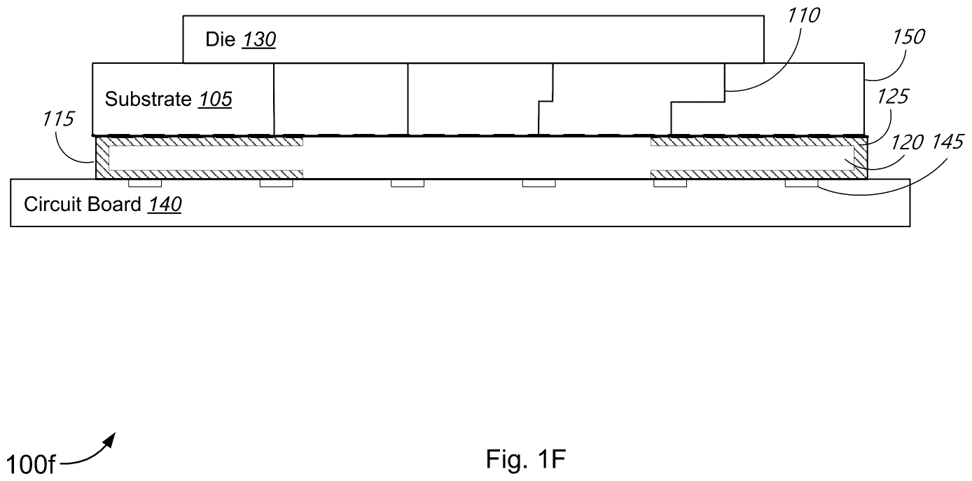

FIGS. 1A-1F (collectively, FIG. 1) are schematic cross-sectional views of a semiconductor device 100a-100f (collectively, semiconductor device 100) with an elastomer substrate layer, in accordance with various embodiments. The semiconductor device 100 includes a substrate 105 with one or more interconnects 110 and an elastomer layer 115. The elastomer layer 115 of the substrate might further include an elastomer body 120 and one or more conductors 125. The semiconductor device 100 might further optionally include a die 130, an interposer 135a (shown in FIG. 1A) or solder balls or bumps 135b (shown in FIG. 1B), and a circuit board 140 with one or more circuit board connections 145. It should be noted that the various components of semiconductor device 100 are schematically illustrated in FIG. 1, and that modifications to the various components, orientations, and other arrangements of semiconductor device 100 may be possible and in accordance with the various embodiments. In addition, although FIGS. 1A-1F, 2A-2E, and 3 are described as separate embodiments for ease of description, a person of ordinary skill would understand that various modifications to each embodiment may be applied to other embodiments.

In various embodiments, the semiconductor device 100 includes a substrate 105. The substrate 105 is a supporting material (e.g., silicon, silicon dioxide, aluminum oxide, gallium, germanium, and/or any other material or combination of materials) upon which or within which elements (e.g., interconnects 110, elastomer layer 115, die 130, interposer 135a, solder balls or bumps 135b, circuit board 140, one or more first layers 150, and/or other elements not shown) of a semiconductor device 100 are fabricated or attached.

The substrate 105 may provide one or more surfaces for die placement (e.g., die 130, and/or other dies (not shown)). In some instances, the die 130 may be semiconductive material comprising one or more active or passive circuit elements for performing electrical functions. The first die 130 may include semiconductor dies, such as flip chip dies. The die 130 may, in some examples, be surface mounted or wire bonded. In some instances, the die 130 may be surface mounted to a surface of an interposer 135a which is then coupled to substrate 105 (as shown in FIG. 1A). The interposer 135a might provide one or more paths (e.g., one or more copper or metal pads, copper or metal traces on or in the substrate layer, through-hole vias, micro bumps, solder balls, copper or metal posts or pillars, and/or other suitable interconnects) to couple (e.g., electrically couple) the die 130 to one or more interconnections 110 of substrate 105. In some examples, the interposer 135a may be an organic interposer. Organic interposers may include interposers formed of organic and/or polymer compounds. In yet further examples, the interposer 135a may include glass, silicon, an organic compound, or a combination of glass, silicon, and/or an organic compound. Alternatively, the first die 130 may be coupled to the substrate 105 via one or more solder balls or bumps 135b (as shown in FIG. 1B). The one or more solder balls or bumps 135b might include, without limitation, one or more pads, micro bumps, posts or pillars, and/or other suitable interconnects to provide one or more interconnections to couple the die 130 to one or more interconnects 110 of substrate 105. The one or more solder balls or bumps 135b may be formed from a conductive material such copper, aluminum, gold, silver, tin, nickel, lead, or a combination of metals/alloy, or may be formed of other electrically conductive material. Alternatively, in other embodiments, the first die 130 may be surface mounted to substrate 105 (as shown in FIGS. 1C-1F).

In some examples, the substrate 105 may include one or more layers or one or more first layers 150 used for component interconnects. Although only one first layer 150 is shown in FIG. 1, there may be more first layers 150 or first layer 150 may itself be formed from one or more layers. The substrate 105 may be a circuit board substrate (e.g., a printed circuit board (“PCB”) substrate). In some cases, the one or more first layers 150 of the substrate 105 may include one or more internal layers (e.g., routing layers). The one or more first layers 150 may include any layer configured to provide component interconnects. For example, routing layers are layers of the substrate through which interconnections may be established between components of the semiconductor device 100. In a non-limiting example, the interconnections may be configured to connect (e.g., electrically connect) the die 130 to the circuit board 140 (e.g., a PCB). Connections may be routed, for example, through the substrate 105 via one or more interconnects 110. The interconnects 110 may include one or more copper or metal pads, copper or metal traces on or in the substrate layer, copper or metal through-hole vias, copper or metal micro bumps, copper or metal solder balls, copper or metal posts or pillars, and/or other suitable interconnects.

The substrate 105 further includes an elastomer layer 115 which may be a routing layer of the substrate 105, part of the one or more first layers 150 of the substrate, or another layer of substrate 105 configured to provide interconnections (e.g., electrical interconnections, conductive interconnections, etc.) between the one or more interconnects 110 and the one or more circuit board connections 145. The elastomer layer 115 is a compliant or flexible layer located between the substrate 105 and the circuit board 140 of the semiconductor package. The elastomer layer 115 may be formed on, deposited on, molded onto, or in contact with the one or more first layers 150 of the substrate 105 as a last layer located between the one or more first layers 150 of the substrate 105 and the circuit board 140.

The elastomer layer 115 may have an elastomer body 120 formed from a compliant or flexible material including, but not limited to, silicone, rubber, resin, and/or any other material or combination of materials capable of providing a compliant or flexible layer. By forming the elastomer layer 115 from a compliant material, the elastomer layer 115 may have a predictable shape and therefore provide predictable signal integrity performance (e.g., predictable insertion loss and predictable return loss) at the substrate 105 to circuit board 140 interface.

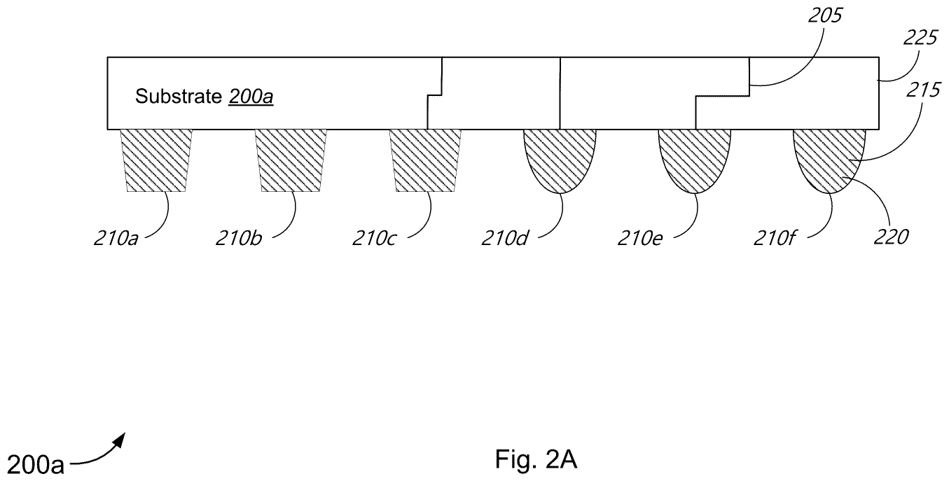

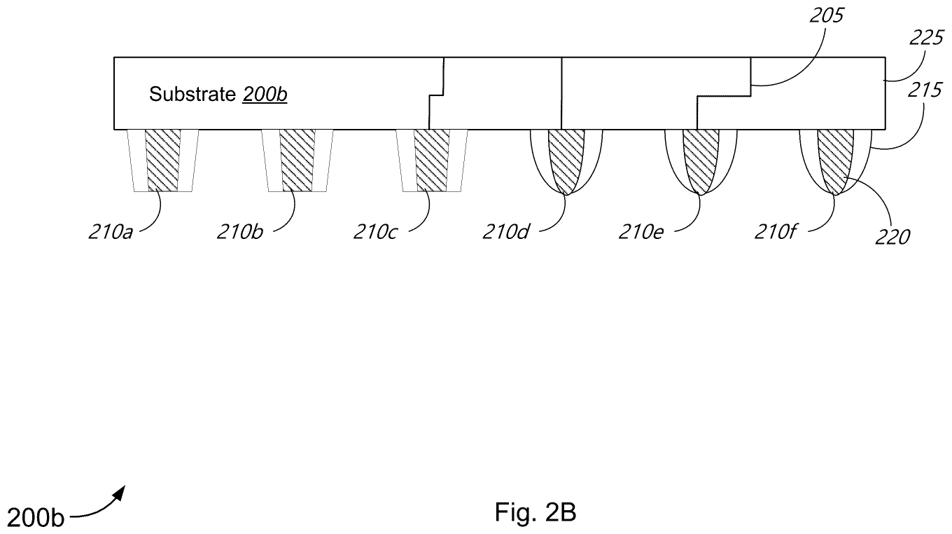

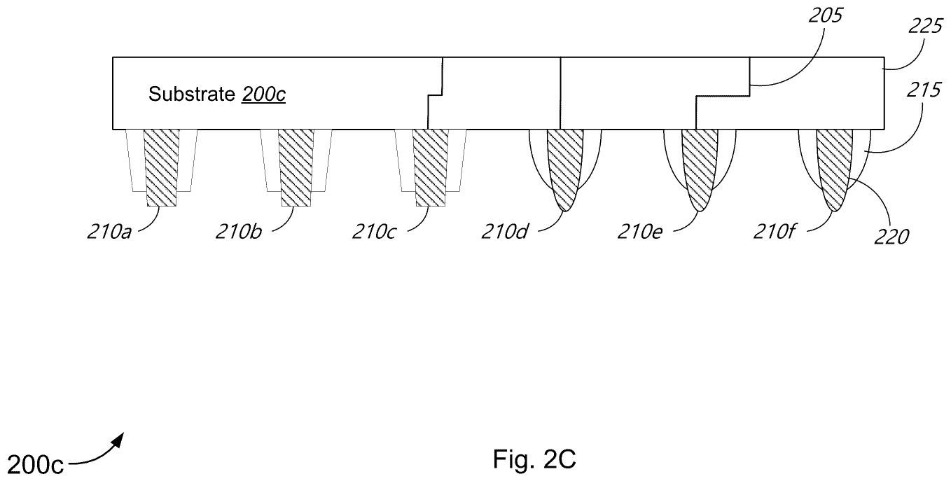

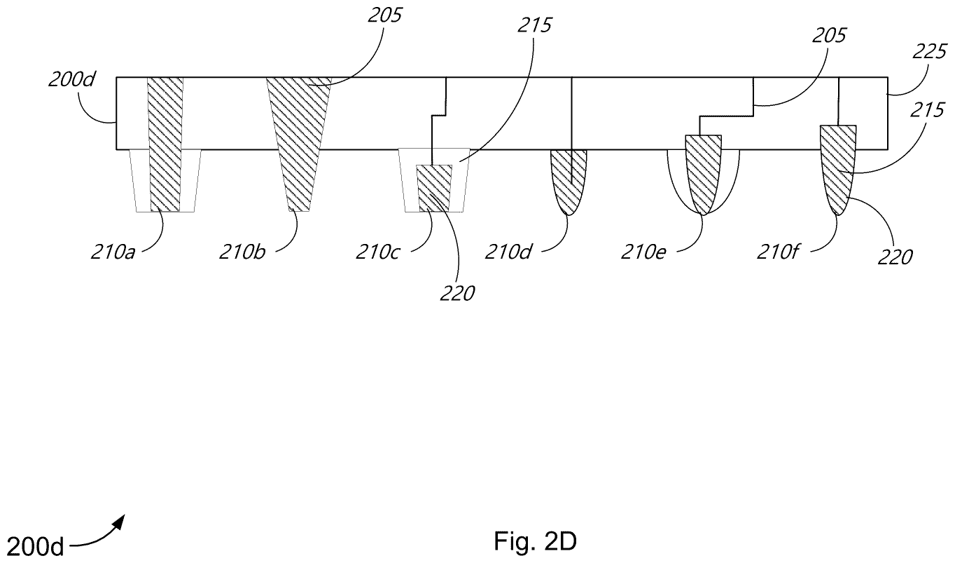

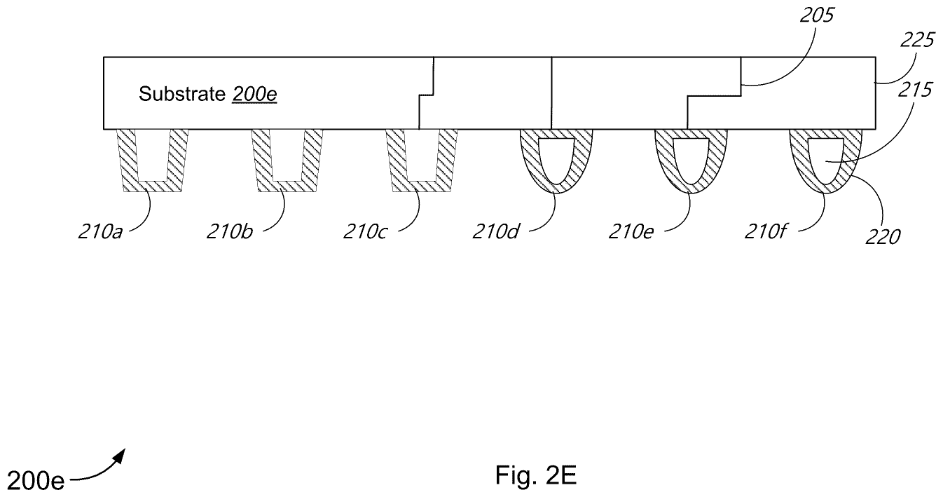

In some cases, as shown in FIG. 1, the elastomer layer 115 can be integrated all along the substrate 105 (e.g., as an elastomer body 120 extending along an axis parallel to a plane defined by a surface of the substrate 105). Alternatively, as shown in FIG. 2, the elastomer layer 115 may be formed as a last layer only in selected locations of the substrate 105.

The elastomer layer 115 might include one or more conductors 125 (identified in the FIGS. 1A-1F with a pattern fill) providing interconnections (e.g., electrical interconnections, conductive interconnections, etc.) between one or more components of the semiconductor device 100. In particular, the one or more conductors 125 might provide interconnections between the one or more interconnects 110 and one or more circuit board connections 145 of the circuit board 140. The one or more conductors 125 might be formed from palladium, gold, copper, aluminum, silver, tin, lead, nickel, and/or any other conductive material or combination of materials capable of providing a conductor. The one or more circuit board connections 145 may include one or more copper or metal pads, copper or metal traces on or in the substrate layer, copper or metal through-hole vias, copper or metal micro bumps, copper or metal solder balls, copper or metal posts or pillars, and/or other suitable interconnects.

In some instances, the elastomer layer 115 might itself be conductive by distributing a plurality of conductors 125 throughout the elastomer body 120 (as shown in FIG. 1A). The plurality of conductors 125 may include one or more conductive balls or particles distributed throughout the elastomer body 120. Alternatively, the one or more conductors 125 might be selectively located within the elastomer body 120 (as shown in FIG. 1B-1D) and/or coat or surround the elastomer body 120 (as shown in FIGS. 1E and 1F).

Turning to FIG. 1A, FIG. 1A shows the elastomer layer 115 itself being conductive by distributing a plurality of conductors 125 throughout the elastomer body 120. In a non-limiting example, a plurality of conductors 125 (e.g., conductive balls or conductive particles) may be mixed with a compliant elastomer material to form the elastomer layer 115. In some instances, the mixture of conductors 125 and the compliant material is placed in a magnetic field causing the conductors to align vertically within the elastomer body 120 (as shown in FIG. 1A). As the elastomer material hardens, one or more electrical pathways may be formed within the elastomer layer 115 via the one or more conductors 125. In some cases, the one or more electrical pathways may be formed when the elastomer layer 115 and/or elastomer body 120 is compressed pushing the one or more conductors 125 together. In this way, the conductive elastomer layer 115 might conduct one or more electrical signals from the one or more interconnects 110 to the circuit board 140.

Alternatively, as shown in FIGS. 1B-1D, the elastomer layer 115 might include the one or more conductors 125a-125f (collectively, conductors 125) selectively distributed in a non-conductive elastomer body 120. Although different types of conductors 125a-125f are shown in FIGS. 1B-1D, the conductors 125 are not limited to only those types. Alternatively, in some cases, only one type of conductor 125 may be used in a substrate 105.

The one or more conductors 125 may be selectively located in the non-conductive elastomer body 120. In a non-limiting example, the one or more conductors may be selectively distributed in the non-conductive elastomer body 120 to align and/or couple at least one conductor of the elastomer layer 115 with at least one of the one or more interconnects 110 of the substrate 105 or to align and/or couple at least one conductor of the elastomer layer 115 with at least one of the one or more circuit board connections 145 of the circuit board 140.

In some instances, the conductors 125a and 125b might be formed from one or more conductive balls filling the elastomer body 120 at selective locations. Alternatively, the conductors 125a and 125b might be a plurality of conductors mixed together with a compliant elastomer material at selective locations within the elastomer layer 115. The selective locations might be chosen within the elastomer layer 115 based on a location of the one or more interconnects 110 and/or a location of the one or more circuit board connections 145. In some instances, the mixture of conductors 125a and 125b and the compliant material are placed in a magnetic field causing the conductors 125a and 125b to align vertically within the elastomer body 120. As the elastomer material hardens, one or more electrical pathways may be formed within the elastomer layer 115 via the one or more conductors 125a and 125b. In some cases, the one or more electrical pathways may be formed when the elastomer layer 115 and/or elastomer body 120 is compressed pushing the one or more conductors 125a and 125b together. In this way, the conductive elastomer layer 115 might conduct one or more electrical signals from the one or more interconnects 110 to the circuit board 140.

Alternatively, in other cases, the conductors 125c-125f might be formed from one or more conductive pins, posts, or bumps filling the elastomer body 120 at selective locations. The one or more conductive pins, posts, or bumps may be square-shaped, rectangle-shaped, trapezoid-shaped, triangle-shaped, circle-shaped, oval-shaped, cone-shaped, and/or any other shape or combination of shapes.

In a non-limiting example, to form the one or more conductors 125c-125f as one or more conductive pins, posts, or bumps at selective locations, one or more holes may be created in the elastomer body 120 and a conductive filler may fill the one or more holes of the elastomer body 120 creating the conductors 125c-125f. The one or more holes might be square-shaped, rectangle-shaped, trapezoid-shaped, triangle-shaped, circle-shaped, oval-shaped, cone-shaped, and/or any other shape or combination of shapes. When the conductive filler is in the one or more holes, the conductors form into the shape of the one or more holes. Alternatively, to form the one or more conductors 125c-125f, the conductors 125c-125f might be formed or deposited as one or more conductive pins, posts, or bumps on one or more respective interconnects 110 and an elastomer material might be formed or molded to surround the substrate 105 and the conductors 125c-125f creating the elastomer layer 115. A circuit board 140 may then be attached to the elastomer layer 115 by aligning and/or coupling the one or more circuit board connections 145 with the one or more conductors 125c-125f In this way, the conductive elastomer layer 115 might conduct one or more electrical signals from the one or more interconnects 110 to the circuit board 140.

In some instances, as shown in FIG. 1C, the one or more conductors 125a-125f might extend from the elastomer body 120 of the elastomer layer 115. By having the one or more conductors 125a-125f extend from elastomer body 120 of the elastomer layer 115, one or more circuit board connections 145 may be easily aligned and/or coupled with the one or more conductors 125a-125f.

In some embodiments, as shown in FIG. 1D, the one or more interconnects 110 might at least partially extend from one or more first layers 150 of the substrate 105 into the elastomer layer 115. Alternatively, in some cases, the one or more conductors may at least partially extend from the elastomer layer 115 into one or more first layers 150 of the substrate 105.

In some cases, the one or more interconnects 110 might form the conductors 125a and 125f. In other words, the one or more interconnects 110 might be the conductors 125a and 125f. In this case, a compliant non-conductive elastomer body 120 may be formed, deposited, and/or molded on the conductors 125a and 125f to form the elastomer layer 115 including the conductors 125a and 125f.

In other cases, the one or more interconnects 110 might partially extend into the elastomer layer 115 and couple to the one or more conductors 125b and 125c. In this case, a compliant non-conductive elastomer body 120 may be formed, deposited, and/or molded on the one or more interconnects 110 to form the elastomer layer 115. In some instances, one or more holes are created in the elastomer body 120 and a conductive filler may fill the one or more holes within the elastomer body 120 creating the conductors 125b and 125c. The one or more holes may be aligned with and/or coupled to the one or more interconnects 110. When the conductive filler is deposited within the holes creating the conductors 125b and 125c, the conductors 125b and 125c are aligned with and/or coupled to the one or more interconnects 110. Alternatively, in other instances, the elastomer body 120 might already include conductors 125b and 125c when it is formed on the one or more interconnects 110. In this instance, the conductors 125b and 125c are aligned with and/or coupled to the one or more interconnects 110.

Alternatively, the one or more conductors 125d and 125e of the elastomer layer 115 might at least partially extend from the elastomer layer 115 into one or more other layers of the substrate 105. In this case, a compliant non-conductive elastomer body 120 may be formed, deposited, and/or molded on the conductors 125d and 125d extending from the substrate 105 to form the elastomer layer 115 of the substrate 105.

Turning to FIGS. 1E and 1F, in other embodiments, the conductor 125 might be configured to coat or surround an outer surface of the elastomer body 120. In some cases, as shown in FIG. 1E, the conductor 125 might fully surround or coat an outer surface of the elastomer body 120. Alternatively, as shown in FIG. 1F, the conductor might only partially or selectively surround the outer surface of the elastomer body 120. The conductor coating or surrounding the outer surface of the elastomer body 120 might provide a conductive path to couple the one or more interconnects 110 to the one or more circuit board connections 145. In some instances, coating or surrounding the outer surface of the elastomer body 120 might be used in conjunction with the other conductors 125 shown in FIGS. 1B-1E.

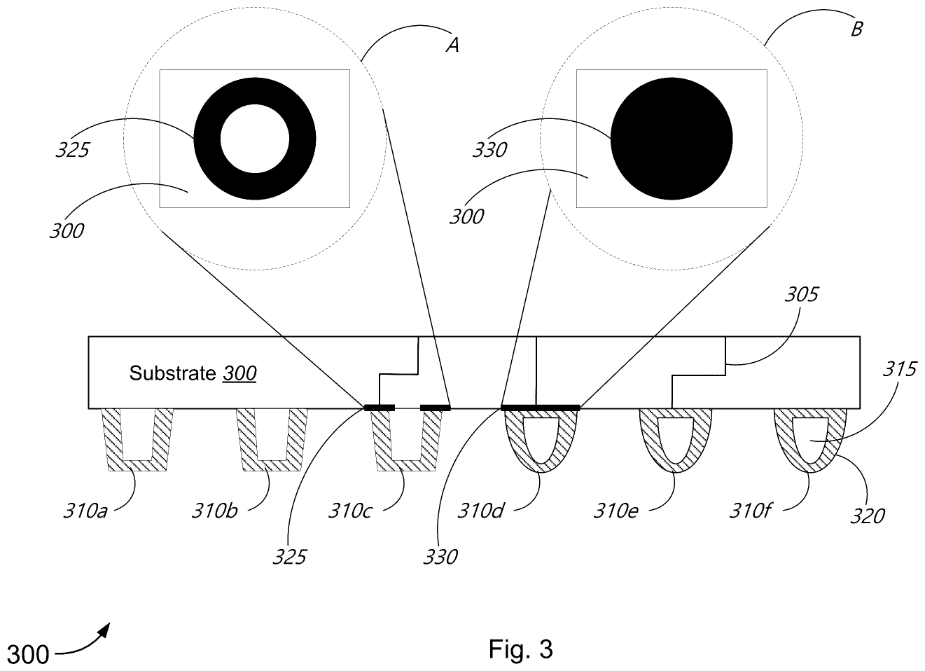

Different arrangements of substrates for semiconductor devices are illustrated below with respect to FIGS. 2-3.

FIGS. 2A-2E (collectively, FIG. 2) are schematic cross-sectional views of substrate arrangements 200a-200e (collectively, substrate 200) with an elastomer layer for a semiconductor module, in accordance with various embodiments. Substrate 200 might be used within semiconductor device 100 of FIG. 1, a printed circuit board (“PCB”), an integrated circuit (“IC”), chip, or other semiconductor device, and/or the like. It should be noted that the various components of substrate 200 are schematically illustrated in FIG. 2, and that modifications to the various components, orientations, and other arrangements of substrate 200 may be possible and in accordance with the various embodiments.

In some examples, the substrate 200 may include one or more first layers 225 used for component interconnects. Although only one first layer 225 is shown in FIG. 2, there may be more first layers 225 or the first layer 225 may itself be formed from one or more layers. In some examples, the one or more first layers 225 of the substrate 200 may include one or more internal layers (e.g., routing layers). In a non-limiting example, the interconnections may be configured to connect the substrate 200 to a circuit board (not shown). Connections may be routed, for example, through the substrate 200 via one or more interconnects 205. The interconnects 205 may be similar to the interconnects 110 of FIG. 1.

The substrate 200 further includes one or more elastomer layers 210a-210f (collectively, elastomer layer 210) which may be a routing layer of the substrate 200, part of the one or more first layers 225 of the substrate 200, or another layer of the substrate 200. The elastomer layer 210 is a compliant layer located between the substrate 200 and a circuit board (not shown) of a semiconductor device. The elastomer layer 210 may be formed on, deposited on, molded onto, or in contact with the one or more first layers 225 of the substrate 200 as a last layer located between the one or more first layers 225 of the substrate 200 and a circuit board.

The elastomer layer 210 may have an elastomer body 215 formed from a compliant material including, but not limited to, silicone, rubber, and/or any other material or combination of materials capable of providing a compliant layer. By forming the elastomer layer 210 from a compliant material, the elastomer layer 210 may have a predictable shape and therefore provide predictable signal integrity performance (e.g., predictable insertion loss and predictable return loss) at the substrate 200 to circuit board interface.

In some cases, as shown in FIG. 2, the elastomer layer 210 is formed as a last layer only in selected locations of the substrate 200. These selective locations may be chosen based on a location of one or more interconnects 205 and/or based on a location of one or more circuit board connections (not shown). In FIG. 2, each elastomer layer 210a-210f is formed at the selective locations on one or more first layers 225 of the substrate 200 as one or more pins (e.g., pins, posts, bumps, and/or the like). The one or more pins, posts, or bumps may be square-shaped, rectangle-shaped, trapezoid-shaped, triangle-shaped, circle-shaped, oval-shaped, cone-shaped, and/or any other shape or combination of shapes formed at selected locations along the substrate 200.

The elastomer layer 210 might include one or more conductors 220 (identified in the FIGS. 2A-2E with a pattern fill) providing interconnections between the substrate 200 and one or more components (e.g., a circuit board). In particular, the one or more conductors 220 might provide interconnections between the one or more interconnects 205 and one or more connections of a circuit board. The one or more conductors 220 might be formed from palladium, gold, copper, aluminum, silver, tin, lead, nickel, and/or any other conductive material or combination of materials capable of providing a conductor.

In some instances, the elastomer layer 210 might itself be conductive by distributing a plurality of conductors 220 throughout the elastomer body 215 (as shown in FIG. 2A). Alternatively, the one or more conductors 220 might be selectively located within the elastomer body 215 (as shown in FIG. 2B-2D) and/or coat or surround the elastomer body 215 (as shown in FIG. 2E). Although different types of elastomer layers 210 are shown in FIGS. 2A-2E, the elastomer layers 210 are not limited to only those types. Alternatively, in some cases, only one type of elastomer layers 210 may be used in a substrate 200.

Turning to FIG. 2A, FIG. 2A shows the elastomer layer 210 itself being conductive by distributing a plurality of conductors 220 (e.g., conductive balls or conductive particles) throughout the elastomer layer 210.

In a non-limiting example, to form the elastomer layer 210 as the one or more pins, posts, or bumps, a plurality of conductors 220 may be mixed together with a compliant elastomer material. In some instances, the mixture of conductors 220 and the compliant material is placed in a magnetic field causing the conductors 220 to align within the elastomer body 215. As the elastomer material hardens, one or more electrical pathways may be formed within the elastomer layer 210 via the one or more conductors 220. In some cases, the one or more electrical pathways may be formed when the elastomer layer 210 and/or elastomer body 215 is compressed pushing the one or more conductors 220 together. In this way, the conductive elastomer layer 210 might conduct one or more electrical signals from the one or more interconnects 205 to a circuit board via the one or more conductors 220.

Alternatively, as shown in FIGS. 2B-2D, the elastomer layers 210a-210f formed as the one or more pins, posts, or bumps might include the one or more conductors 220 contained in a non-conductive elastomer body 215.

The one or more elastomer layers 210 may be selectively distributed as a last layer of the substrate 200 to align and/or couple at least one conductor 220 of the elastomer layer 210 with at least one of the one or more interconnects 205 of the substrate 200 or to align and/or couple at least one conductor 220 of the elastomer layer 210 with at least one of one or more circuit board connections of a circuit board.

In some instances, the conductors 220 might be formed from one or more conductive balls or particles filling the elastomer body 215 of the elastomer layer 210 at selective locations. Alternatively, the conductors 220 might be a plurality of conductors mixed together with a compliant elastomer material at selective locations within the elastomer layer 210. The selective locations might be chosen within the elastomer layer 210 based on a location of the one or more interconnects 205 and/or a location of the one or more conductive circuit board connectors. Alternatively, in other cases, the conductors 220 might be formed as one or more conductive pins, posts, or bumps filling the elastomer body 215 at selective locations. The one or more conductive pins, posts, or bumps may be square-shaped, rectangle-shaped, trapezoid-shaped, triangle-shaped, circle-shaped, oval-shaped, cone-shaped, and/or any other shape or combination of shapes.

In a non-limiting example, to form the one or more conductors 220, one or more holes may be created in the elastomer body 215 and a conductive filler may fill the one or more holes of the elastomer body 215 creating the conductors 220 as the one or more conductive pins, posts, or bumps. The one or more holes might be square-shaped, rectangle-shaped, trapezoid-shaped, triangle-shaped, circle-shaped, oval-shaped, cone-shaped, and/or any other shape or combination of shapes. When the conductive filler is deposited in the one or more holes, the conductors 220 form into the shape of the one or more holes. Alternatively, to form the one or more conductors 220, the conductors 220 might be formed or deposited as one or more conductive pins, posts, or bumps at selective locations on one or more respective interconnects 205 and an elastomer material might be formed, deposited, or molded to surround the interconnects 205 and the conductors 220 creating the elastomer layer 210.

In some instances, as shown in FIG. 2C, the one or more conductors 220 might extend from the elastomer body 215 of the elastomer layer 210. By having the one or more conductors 220 extend from elastomer body 215 of the elastomer layer 210, one or more circuit board connectors may be easily aligned with and/or coupled to the one or more conductors 220.

In some embodiments, as shown in FIG. 2D, the one or more interconnects 205 might at least partially extend from one or more first layers 225 of the substrate 200 into the elastomer layer 210. Alternatively, in some cases, the one or more conductors 220 or conductive elastomer layer 210 may at least partially extend from the elastomer layer 210 into one or more first layers 225 of the substrate 200.

In some cases, the one or more interconnects 205 might form the conductor 220 as shown in elastomer layer 210a. In this case, a compliant non-conductive elastomer body 215 may be formed, deposited, and/or molded on the conductors 220 to form the elastomer layer 210a. In other cases, a conductive elastomer layer 210b forms the one or more interconnects 205.

In other cases, the one or more interconnects 205 might partially extend into the elastomer layer 210c and 210d and couple to the one or more conductors 220. In this case, a compliant non-conductive elastomer body 215 may be formed, deposited, and/or molded on the one or more interconnects 205 to form the elastomer layers 210c and 210d. In some instances, one or more holes are created in the elastomer body 215 and a conductive filler may fill the one or more holes of the elastomer body 215 creating the conductors 220. The one or more holes may be aligned with and/or coupled to the one or more interconnects 205. When the conductive filler is deposited or contained within the holes creating the conductors 220, the conductors 220 are aligned with and/or coupled to the or more interconnects 205. Alternatively, in other instances, the elastomer body 215 might already include conductors 220 when it is formed or deposited on the one or more interconnects 205. In this instance, the conductors 220 are aligned with and/or coupled to the one or more interconnects 205 to form the elastomer layers 210c and 210d.

Alternatively, the one or more conductors 220 of the elastomer layer 210e and/or the conductive elastomer layer 210f might at least partially extend into one or more other layers of the substrate 200. In this case, a compliant non-conductive elastomer body 215 may be formed, deposited, and/or molded on the conductors 220 extending from the substrate 200 to form the elastomer layer 210e and/or the elastomer layer 210f may be formed or deposited in one or more other layers of the substrate 200.

Turning to FIG. 2E, in other embodiments, the conductor 220 might be configured to coat or surround an outer surface of the elastomer body 215 of the elastomer layer 210 formed as the one or more pins, posts, or bumps. In some cases, as shown in elastomer layers 210a-210c, the conductor 220 might only partially or selectively surround the outer surface of the elastomer body 215. Alternatively, as shown in elastomer layers 210d-210f, the conductor 220 might fully surround or coat an outer surface of the elastomer body. The conductor 220 coating or surrounding the outer surface of the elastomer body 215 might provide a conductive path to couple the one or more interconnects 205 to one or more conductive circuit board connectors. In some instances, coating or surrounding the outer surface of the elastomer body 215 might be used in conjunction with the other conductors 220 shown in FIGS. 1B-1D.

Different arrangements of substrates for semiconductor devices are illustrated below with respect to FIG. 3.

FIG. 3 is a schematic cross-sectional view of a substrate arrangement 300 with a bottom view of one or more ring pad connections or solid pad connections to connect the one or more conductors of the elastomer layer to one or more other layers of the substrate 300, in accordance with various embodiments. Elements of substrate 300 might be used within semiconductor device 100 of FIG. 1, substrate 200 of FIG. 2, a printed circuit board (“PCB”), an integrated circuit (“IC”), chip, or other semiconductor device, and/or the like. It should be noted that the various components of substrate 300 are schematically illustrated in FIG. 3, and that modifications to the various components, orientations, and other arrangements of substrate 300 may be possible and in accordance with the various embodiments.

In some examples, the substrate 300 may include one or more respective layers used for component interconnects. Connections may be routed, for example, through the substrate 300 via one or more interconnects 305 which may be similar to interconnects 110 and 205 of FIGS. 1 and 2.

The substrate 300 further includes one or more elastomer layers 310a-310f (collectively, elastomer layer 310) which may be a layer of the substrate 300. The elastomer layer 310 is a compliant layer located between the substrate 300 and a circuit board (not shown) of a semiconductor device. The elastomer layer 310 may be formed on, deposited on, or molded onto one or more layers of the substrate 300 as a last layer located between the substrate 300 and a circuit board. The elastomer layer 310 may include an elastomer body 315 and a conductor 320 (identified in FIG. 3 with a pattern fill). The elastomer layer 310 may be similar to elastomer layers 115 and 210 described in FIGS. 1 and 2.

The substrate 300 might additionally include one or more ring pad connectors 325 and/or solid pad connectors 330 for coupling (e.g., electrically coupling) the one or more interconnects 305 to the one or more conductors 320 of the elastomer layer 310. These ring pad connectors 325 and/or solid pad connectors 330 may also be used at the elastomer layer 310 to circuit board interface (not shown). Zoomed in circle A represents a bottom view of the one or more ring pad connectors 325 located on substrate 300. Zoomed in circle B represents a bottom view of the one or more solid pad connectors 330 located on substrate 300. In some cases, the one or more elastomer layers 310 and/or conductors 320 may be formed on the one or more ring pad connectors 325 and/or solid pad connectors 330. In some cases, before forming or depositing the one or more elastomer layers 310 and/or conductors 320 on the one or more ring pad connectors 325 and/or solid pad connectors 330, the conductors 320 and/or the one or more ring pad connectors 325 and/or solid pad connectors 330 may be coated or covered in a conductive material to further facilitate the electrical coupling of the one or more interconnects 305 to the one or more conductors 320 of the elastomer layer 310.

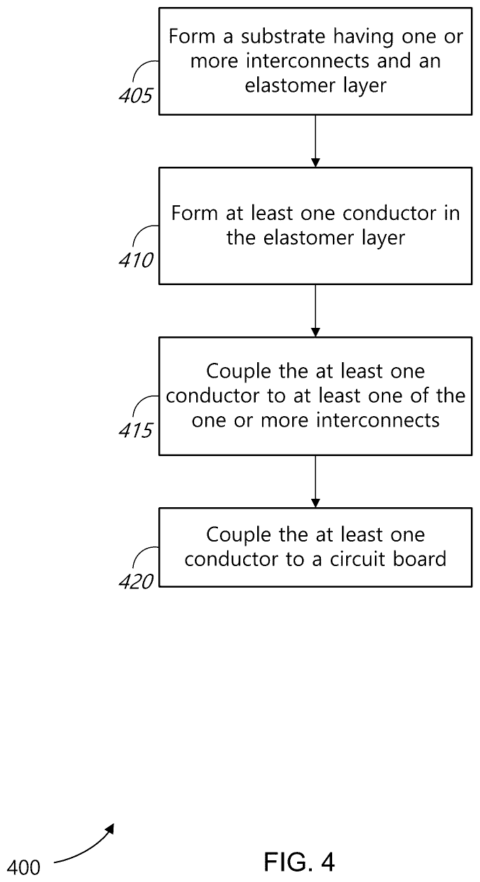

FIG. 4 is a flow diagram of a method 400 of manufacturing a substrate with an elastomer layer, in accordance with various embodiments. The method 400 includes, at block 405, forming a substrate comprising (i) one or more interconnects and (ii) an elastomer layer. As previously described, the substrate may be a circuit board substrate (e.g., a printed circuit board (“PCB”) substrate. The substrate may include one or more respective layers used for component interconnects. For example, the one or more layers are layers of the substrate through which interconnections may be established between components of a semiconductor package or semiconductor device. In a non-limiting example, the interconnections may be configured to connect the substrate to a circuit board (e.g., a PCB). The connections may be routed, for example, through the substrate 105 via one or more conductive substrate connections. The interconnects may include one or more copper or metal pads, copper or metal traces on or in the substrate layer, copper or metal through-hole vias, copper or metal micro bumps, copper or metal solder balls, copper or metal posts or pillars, and/or other suitable interconnects.

As previously described, the elastomer layer is a compliant or flexible layer located between the substrate and a circuit board of a semiconductor device. The elastomer layer may be formed on one or more layers of the substrate as a last layer located between the substrate and a circuit board. The elastomer layer may include an elastomer body and at least one conductor.

In some cases, the elastomer layer is formed on a surface of the substrate to substantially or entirely coat, cover, or surround a surface of the substrate as a body extending along an axis parallel to a plane defined by the surface of the substrate as shown in FIG. 1. Alternatively, in other cases, as shown in FIG. 2, the elastomer layer is deposited at selected locations along the surface of the substrate such that the elastomer layer only partially coats or covers the surface of the substrate at the selected locations. In some instances, as shown in FIG. 2, the elastomer layer may be deposited as at least one pin, bump, or post at the selected locations of the substrate.

In some instances, the elastomer layer itself is the conductor as described in FIGS. 1A and 2A. Alternatively, in other cases, the elastomer layer comprises one or more conductors selectively distributed within the elastomer body as described in FIGS. 1B-1D and FIGS. 2B-2D. Alternatively, in yet other cases, the elastomer layer may be coated or covered with the conductor such that the conductor either fully or partially surrounds the elastomer body as described in FIGS. 1E and 1F and FIG. 2E.

In various cases, before depositing the elastomer layer, a surface of the one or more interconnects and/or a surface of the elastomer layer and/or the at least one conductor might be coated or covered in a conductive material to facilitate the coupling (e.g., electrical coupling) of the one or more interconnects to the elastomer layer and/or the at least one conductor.

The method 400 continues, at block 415, by coupling the at least one conductor of the elastomer layer to at least one of the one or more interconnects of the substrate.

As previously described, this coupling of the at least one conductor of the elastomer layer to the least one of the one or more interconnects of the substrate may occur in a couple of different ways. If the elastomer layer itself is the conductor, then the elastomer layer may be placed and formed on the one or more interconnects of the substrate.

Alternatively, if the elastomer layer comprises one or more conductors selectively distributed within an elastomer body, then the one or more conductors may be coupled to and/or aligned with and formed on the one or more interconnects. Next, the elastomer body may be formed or molded to surround the one or more conductors and the one or more interconnects. Alternatively, if the elastomer layer comprises one or more conductors selectively distributed within an elastomer body, then the elastomer body may first be formed or molded on the one or more interconnects. Next, the elastomer body might contain one or more holes configured to receive a conductive filler. The one or more holes might be aligned with and/or coupled to the one or more interconnects. The conductive filler might next be deposited in the one or more holes to create the conductor and to couple the conductor to the one or more interconnects.

Alternatively, if the elastomer layer is coated or covered with the conductor such that the conductor either fully or partially surrounds the elastomer body, then the elastomer body might first be formed and coated in the conductor. Next, the conductor might be aligned with or coupled to the one or more interconnects and the elastomer layer might be formed or molded on the one or more interconnects of the substrate to couple the conductor to the one or more interconnects of the substrate.

The method 400, at block 420 might continue, by coupling the at least one conductor to a circuit board. As previously described, by coupling the at least one conductor to a circuit board, the conductor of the elastomer layer may be used to couple the one or more interconnects of the substrate to the circuit board.

The techniques and processes described above with respect to various embodiments may be used to manufacture semiconductor device 100 and/or substrates 200 and 300, and/or components thereof, as described herein.

While some features and aspects have been described with respect to the embodiments, one skilled in the art will recognize that numerous modifications are possible. For example, the methods and processes described herein may be implemented using hardware components, custom integrated circuits (ICs), programmable logic, and/or any combination thereof. Further, while various methods and processes described herein may be described with respect to particular structural and/or functional components for ease of description, methods provided by various embodiments are not limited to any particular structural and/or functional architecture but instead can be implemented in any suitable hardware configuration. Similarly, while some functionality is ascribed to one or more system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with or without some features for ease of description and to illustrate aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

What is claimed is:

1. A substrate comprising:
one or more interconnects; and
an elastomer layer comprising at least one conductor, wherein the at least one conductor is configured to couple at least one of the one or more interconnects of the substrate to a circuit board.

2. The substrate of claim 1, wherein the one or more interconnects at least partially extend into the elastomer layer to form or to couple to the at least one conductor of the elastomer layer.

3. The substrate of claim 1, wherein the elastomer layer further comprises a non-conductive elastomer body, and wherein the at least one conductor of the elastomer layer is contained within the non-conductive elastomer body.

4. The substrate of claim 1, wherein the elastomer layer further comprises a non-conductive elastomer body, and wherein the at least one conductor of the elastomer layer surrounds an outer surface of the non-conductive elastomer body.

5. The substrate of claim 1, wherein the elastomer layer is at least one pin comprising the at least one conductor.

6. The substrate of claim 5, wherein the at least one conductor at least partially surrounds an outer surface of a non-conductive body of the at least one pin.

7. A semiconductor package comprising:
a first die; and
a substrate coupled to the first die, the substrate comprising one or more interconnects and an elastomer layer comprising at least one conductor, wherein the at least one conductor is configured to couple at least one of the one or more interconnects of the substrate to a circuit board.

8. The semiconductor package of claim 7, wherein the one or more interconnects at least partially extend into the elastomer layer to form or to couple to the at least one conductor of the elastomer layer.

9. The semiconductor package of claim 7, wherein the elastomer layer is at least one pin comprising the at least one conductor.

10. A method comprising:
forming a substrate comprising (i) one or more interconnects and (ii) an elastomer layer, the elastomer layer comprising at least one conductor, wherein the elastomer layer is formed to couple at least one of the one or more interconnects of the substrate to a circuit board via the at least one conductor.

11. The method of claim 10, wherein the one or more interconnects or the circuit board comprise one or more ring pad connections or one or more solid pad connections.

12. The method of claim 10, wherein the one or more interconnects at least partially extend into the elastomer layer to form or to couple to the at least one conductor of the elastomer layer, and wherein the elastomer layer is formed on the one or more interconnects to surround the one or more interconnects at least partially extending into the elastomer layer.

13. The method of claim 10, wherein the elastomer layer further comprises a non-conductive elastomer body and wherein the at least one conductor of the elastomer layer is contained within the non-conductive elastomer body.

14. The method of claim 13, wherein the at least one conductor of the elastomer layer at least partially extends from the non-conductive elastomer body to couple to the circuit board.

15. The method of claim 10, wherein the elastomer layer is the at least one conductor.

16. The method of claim 10, wherein the elastomer layer is formed as at least one pin comprising the at least one conductor, and wherein the at least one pin couples the at least one conductor to the at least one of the one or more interconnects of the substrate.

17. The method of claim 16, wherein the at least one pin comprises a non-conductive elastomer body and the at least one conductor at least partially coats an outer surface of the non-conductive elastomer body.

18. The method of claim 10, wherein the elastomer layer comprises a non-conductive elastomer body, and wherein the method further comprises:
coating at least part of an outer surface of the non-conductive elastomer body with the at least one conductor.

19. The method of claim 10, wherein the elastomer layer comprises a non-conductive elastomer body, and wherein the method further comprises:
coating the at least one of the one or more interconnects with a conductive material;
coating at least part of an outer surface of the non-conductive elastomer body with the at least one conductor; and
forming the elastomer layer on the at least one of the one or more interconnects by coupling the at least one conductor of the elastomer layer to the at least one of the one or more interconnects coated with the conductive material.

20. The method of claim 10, wherein the elastomer layer is formed on a surface of one or more first layers of the substrate as a body extending along an axis parallel to a plane defined by the surface of the one or more first layers of the substrate.
